(19) United States
(12) Patent Application Publication
(10) Pub. No.: US 2014/0151884 A1
(43) Pub. Date: Jun. 5, 2014

(54) SELF-FORMING BARRIER STRUCTURE AND SEMICONDUCTOR DEVICE HAVING THE SAME

(71) Applicant: INDUSTRIAL TECHNOLOGY RESEARCH INSTITUTE, Hsin-Chu (TW)

(72) Inventors: Wen-Hsi Lee, Kaohsiung (TW); Chia-Yang Wu, Tainan (TW)

(73) Assignee: INDUSTRIAL TECHNOLOGY RESEARCH INSTITUTE, Hsin-Chu (TW)

(21) Appl. No.: 13/865,847

(22) Filed: Apr. 18, 2013

(30) Foreign Application Priority Data
Nov. 30, 2012 (TW) 101145053

(51) Int. Cl. H01L 23/532

(52) U.S. Cl. CPC H01L 23/53238
USPC 257/751

(57) ABSTRACT

A self-forming barrier structure and a semiconductor device using the same are disclosed. The self-forming barrier structure includes a silicon-containing substrate; a first barrier layer formed on the silicon-containing substrate; and a second barrier layer formed of a copper-containing alloy on the first barrier layer; wherein the copper-containing alloy comprises copper and at least one other metal which diffuses faster than copper and is not inter-miscible with copper.

### CROSS_REFERENCE TO RELATED APPLICATIONS

This application claims the benefit of Taiwan application Serial No. 101145053, filed Nov. 30, 2012, the disclosure of which is incorporated by reference herein in its entirety.

### TECHNICAL FIELD

The present disclosure relates to the field of semiconductor device, and more particularly, to a self-forming barrier structure and a semiconductor device using the same.

### TECHNICAL BACKGROUND

Recently, the semiconductor manufacturing technology has advanced to the ultra-large-scale integration (ULSI). The Semiconductor Industry Association (SIA) of America has expected in the National Technology Roadmap for Semiconductors (NTRS) that the minimum feature length of semiconductor device will shrink to 32 nm or even 22 nm. Once the expectation is reached, the metallic interconnection has to be much layered and sophisticated. To avoid the electron-migration effect caused by a high operating current density and the time delay effect due to parasitic resistor and capacitor in the interface between metal and dielectric layers, metal material of high conductivity and high melting point as well as dielectric material of low dielectric constant are required to improve the device performance.

However, there still exist many problems in the Cu metallization of semiconductor manufacturing, including: (1) Cu cannot form a self-protective layer on its surface. The Cu coating is subject to oxidization and moisture corrosion in the atmospheric circumstance, which may decline metallization stability. (2) Cu may react with silicon or Si-based material at a temperature of more than 200° C. , so as to produce a Cu silicide such as Cu₃Si in the integrated circuit which causes the devices to fail. (3) The adherence between Cu and dielectric is not good, which causes less mechanical strength in the integrated-circuit layered structure. (4) Cu atoms are inclined to diffuse. Electrical fields can be further used to enhance the diffusion of Cu atoms through a dielectric layer into Si-based substrate, producing deep level acceptors which may decline device performance. (5) It is difficult to pattern a Cu film by the reactive-ion etching (RIE) due to Cu's very low vapor pressure in the plasma.

Regarding the above-mentioned problems, some possible solutions have been proposed as follows: (1) Diffusion barriers of high thermal and chemical stability have been used to retard the Cu atom diffusion, to prevent interaction between Cu and Si-based materials, and to improve adhesion between Cu and dielectric materials. (2) Both the metal inlaid Damascene processing and the chemical mechanical polishing (CMP) are used to improve the sophisticated patterning and etching process. (3) Metal (e.g. Al, Mn) dopants are used to form a self-protective layer on the Cu surface, which can protect the Cu film from being oxidized or moisture-corroded.

Moreover, it is difficult to fill up via in the metal layer in the Cu metallization, and the main factors can be the barrier's thickness and resistivity. There exist some problems in the via filling process, caused by the defects of dis-continuity, overhang and asymmetry in the formation of barrier and crystal-seed layers. In the case that Cu is used to fill the via in order to diminish the resistivity, the barrier's thickness may also be reduced, which will cause the above-mentioned defects of dis-continuity and asymmetry as well as a downgraded performance. On the other hand, the barrier's thickness may be increased in order to improve the anti-diffusivity, which will cause the above-mentioned defect of overhang and an increase in the resistivity. So, thickness and resistivity are two main considerations for an optimum barrier structure.

### TECHNICAL SUMMARY

One embodiment of the disclosureprovides a self-forming barrier structure comprising: a silicon-containing substrate; a first barrier layer formed on the silicon-containing substrate; and a second barrier layer formed of a copper-containing alloy on the first barrier layer; wherein the copper-containing alloy comprises copper and at least one other metal which diffuses faster than copper and is not inter-miscible with copper.

One embodiment of the disclosure provides a semiconductor device having a self-forming barrier, comprising: a trenched semiconductor structure; a first barrier layer formed on the trenched semiconductor structure; and a second barrier layer formed of a copper-containing alloy on the first barrier layer; wherein the copper-containing alloy comprises copper and at least one other metal which diffuses faster than copper and is not inter-miscible with copper.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 shows a cross-sectional view of a self-forming barrier structure according to a first embodiment of the present disclosure.

FIG. 2 shows a cross-sectional view of a semiconductor device having a self-forming barrier according to a second embodiment of the present disclosure.

FIG. 3 shows a schematic diagram of the self-forming barrier structure with two barrier layers.

FIG. 4a shows the effective resistivity of the self-forming barrier structure with various compositions of Cu—Mn alloy in the second barrier layer, plotted versus the RTA temperatures.

FIG. 4b shows the effective resistivity of the self-forming barrier structure with a RuN layer in the first barrier layer and various compositions of Cu—Mn alloy in the second barrier layer, plotted versus the RTA temperatures.

### DESCRIPTION OF THE EXEMPLARY EMBODIMENTS

For further understanding and recognizing the fulfilled functions and structural characteristics of the disclosure, several exemplary embodiments cooperating with detailed description are presented as the following. Reference will now be made in detail to the preferred embodiments, examples of which are illustrated in the accompanying drawings.

In the following description of the embodiments, it is to be understood that when an element such as a layer (film), region, pattern, or structure is stated as being “on” or “under” another element, it can be “directly” on or under another element or can be “indirectly” formed such that an intervening element is also present. Also, the terms such as “on” or “under” should be understood on the basis of the drawings, and they may be used herein to represent the relationship of one element to another element as illustrated in the figures. It will be understood that this expression is intended to encompass different orientations of the elements in addition to the orientation depicted in the figures, namely, to encompass both “on” and “under”. In addition, although the terms “first”, “second” and “third” are used to describe various elements, these elements should not be limited by the term. Also, unless otherwise defined, all terms are intended to have the same meaning as commonly understood by one of ordinary skill in the art.

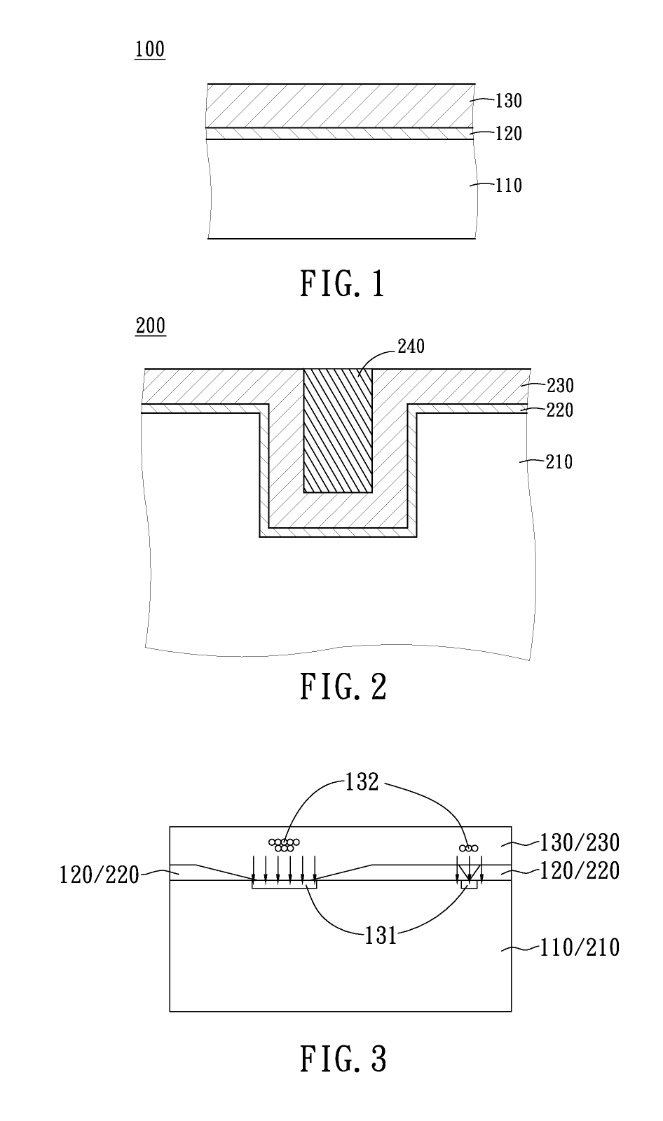

FIG. 1 schematically shows a cross-sectional view of a self-forming barrier structure 100 according to a first embodiment of the present disclosure. The self-forming barrier structure 100 includes a silicon-containing substrate 110, a first barrier layer 120, and a second barrier layer 130. The silicon-containing substrate 110 can be made of silicon (Si), Si oxide, or the combination of Si and Si oxide, and is used to support and carry the first barrier layer 120 and the second barrier layer 130.

The first barrier layer 120 is disposed on the silicon-containing substrate 110, so as to cover the silicon-containing substrate 110 with the first barrier layer 120. The first barrier layer 120 can be made of various barrier metal materials such as copper (Cu), aluminum (Al), ruthenium (Ru), tantalum (Ta) and titanium (Ta). Resistivity behaviors of the above-mentioned metals for the first barrier layer 120 in the embodiment are listed in Table I. As can be observed in Table I, Ru has an effective resistivity of 10.77 μΩ-cm, less than that (17.26 μΩ-cm) of Ta. This suggests that a Ru barrier layer can have a five eighth thickness of a Ta barrier layer to get the same resistivity. Also, Table II summarizes crystal comparisons between Cu and various barrier metal materials including Cu, Ru and Ta. Two crystals can be regarded as being matched to each other if the lattice mismatch therebetween is less than 20%. It can be seen in the Table II that the lattice mismatch between Ru and Cu(111) is in a range between 17% and 19%, so their crystal lattices are quite matched to each other.

TABLE I
Resistivity behaviors of metals for the first barrier
layer in the embodiment.

| | Bulk resistivity | Wavelength | Effective resistivity in 20 nm |
|---|---|---|---|
| Metal | (in μΩ-cm) | (in nm) | (in μΩ-cm) |
| Cu | 1.7 | 39 | 5.02 |
| Al | 2.7 | 14.8 | 4.70 |
| Ru | 7.13 | 10.2 | 10.77 |
| Ta | 14.5 | 3.81 | 17.26 |
| Ti | 42.1 | 0.83 | 43.85 |

TABLE II
Crystal comparisons between Cu and various barrier metal materials

| | | | | Lattice |
|---|---|---|---|---|
| | | | | mismatch |
| | Crystal | Lattice | Nearest atomic | with |
| Metal | structure | constant (Å) | distance (Å) | Cu(111) |
| Cu | fcc | a = b = c = 2.61 | Cu(111) = 2.552 | 0% |
| Ru | hcp | a = b = 2.7, c = 4.28 | Ru(101) = 2.052 | 19.59% |
| | | | Ru(002) = 2.11 | 17.32% |
| Ta | bcc | a = b = c = 3.3 | Ta(002) = 1.905 | 25.35% |

To introduce Ru into the next-generation manufacturing of semiconductor devices, its diffusion barrier has to be raised. There are two means to reduce the diffusion length of a barrier material. The first one is to increase its crystal grain size, and the other one is to dope some dopants in the barrier material to convert its poly-crystalline structure into its micro-crystalline or amorphous structure. Therefore, the first barrier layer 120 can be formed of Ru on the silicon-containing substrate 110, and nitrogen (Ni) gas is introduced to the Ru film in the fabrication process, so that Ru is formed in its micro-crystalline or amorphous structure to increase the first barrier layer's 120 diffusion barrier. Due to the introduction of the Ni gas, the first barrier layer 120 may further comprise ruthenium nitride (RuN).

The second barrier layer 130 is disposed on the first barrier layer 120, so as to cover the first barrier layer 120 with the second barrier layer 130. The second barrier layer 130 is formed of a copper-containing alloy, comprising Cu and at least one other metal which diffuses faster than Cu and is not inter-miscible with Cu. In the embodiment, the at least one other metal acts as a dopant, to be doped in Cu to form a self-forming barrier.

The dopant is used not only to improve thermal stability in the barrier structure 100, but also to diminish total electrical resistivity in the barrier structure 100. Therefore, a proper dopant material in the embodiment may have the following requirements: (1) The dopant material need to be not inter-miscible with Cu and can be deposited by the sputtering process, so that the composition of the dopant film can be well controlled; (2) The dopant material need to diffuse faster than Cu, so that a barrier layer can be formed on a dielectric interface; (3) The dopant material can oxidized to be an oxide having a free energy as small as possible, so that the dopant can be driven to a dielectric interface to form the oxide; wherein its free energy has to be approximately smaller than that of Si dioxide (SiO₂) to protect the dopant from penetrating into the oxide layer once the barrier layer is formed; (4) The dopant material need to have an activation energy index approximated to or larger than 1 in a liquid environment, so that the dopant can be moved onto the interface. In the manufacturing of the self-forming barrier structure 100, the process factors such as dopant concentration, layer thickness and annealing temperature should be considered according to the application of the barrier structure 100, because the process factors will affect its diffusion barrier. Consequently, manganese (Mn) is used as the dopant material in the second barrier layer 130 in the embodiment.

In accordance with the above description, the first barrier layer 120 can improve thermal stability, and the second barrier layer 130 can have a less thickness, due to existence of the first barrier layer 120, to reduce participation rate of the second barrier layer 130 in recesses on the silicon-containing substrate 110, so as to decrease the total resistivity of the barrier structure 100. This may facilitate the movement of the Mn atoms in the second barrier layer 130 towards the interface between the silicon-containing substrate 110 and the first barrier layer 120 during a subsequent annealing process, so as to prevent the Mn atoms from remaining in the Cu crystal structure, which may cause an increased resistivity and defects in the second barrier layer 130. Also, the second barrier layer 130 can be configured for mending some diffusion paths formed at the locations where the first barrier layer 120 has a thin thickness. In other words, as shown in FIG. 3, the Mn atoms 132 in the second barrier layer 130 can pass along the diffusion paths to the interface between the silicon-containing substrate 110 and the first barrier layer 120 and fill up recesses 131 on the surface of the silicon-containing substrate 110. The Mn atoms 132 penetrating through the first barrier layer 120 may react with the silicon-containing substrate 110 to produce a manganese-silicon (MnSi) oxide, of which a third barrier layer is further formed on the silicon-containing substrate 110. In such an embodiment, the first barrier layer 120 may have a thickness in the range between 1 nm and 10 nm, and the second barrier layer 130 may have a thickness in the range between 50 nm and 150 nm.

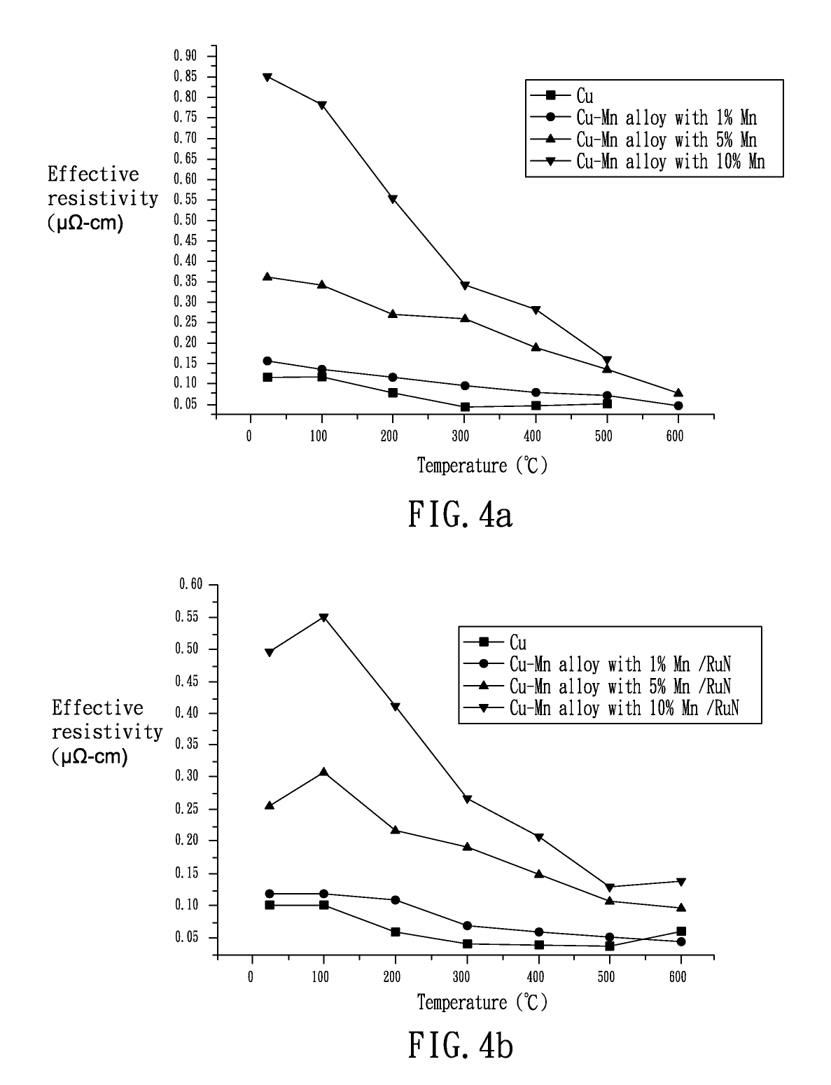

In the following paragraph, we will explore resistivities of the second barrier layer 130 doped with various dopants and formed at different annealing temperatures. In one embodiment, the first barrier layer 120 of 10-nm thickness is deposited on the silicon-containing substrate 110 by sputtering Ru atoms in a chamber filled with Ni and argon (Ar) gases, wherein Ar acts as a protective gas in the sputtering process and Ni is introduced to assist the Ru atoms in forming in the micro-crystalline or amorphous structure, in order to raise the diffusion barrier of the first barrier layer 120. Next, the second barrier layer 130 of 50-nm thickness is deposited on the first barrier layer 120 by sputtering a Cu—Mn alloy with 0%, 1%, 5% or 10% Mn. To understand thermal stability of the alloy film and the silicon-containing substrate 110 as well as annealing-temperature-dependent resistivity of the self-forming barrier structure 100, the barrier structure 100 is treated in the rapid thermal annealing (RTA) process and measured in real time. FIG. 4a shows the effective resistivity (μΩ-cm) of the self-forming barrier structure 100 with various compositions of Cu—Mn alloy in the second barrier layer 130, plotted versus the RTA temperatures ( ). As can be observed in FIG. 4a, all the resistivity curves go down as the RTA temperature goes up. If the barrier structure 100 has a RuN layer in the first barrier layer 120, FIG. 4b shows its effective resistivity with various compositions of Cu—Mn alloy in the second barrier layer 130, plotted versus the RTA temperatures. As can be observed in FIG. 4b, all the resistivity curves also go down as the RTA temperature goes up. Comparing FIG. 4a with FIG. 4b, the resistivity of the barrier structure 100 with the RuN layer is less than that of the barrier structure 100 without the RuN layer at the same RTA temperature.

FIG. 2 schematically shows a cross-sectional view of a semiconductor device 200 having a self-forming barrier according to a second embodiment of the present disclosure. The main structure and fabrication process of the semiconductor device 200 are similar to the barrier structure 100 in the first embodiment, except that the silicon-containing substrate 110 is replaced by a trenched semiconductor structure 210 as shown in FIG. 2, to be applied to the Cu-interconnection semiconductor manufacturing. The trenched semiconductor structure 210 can be composed of at least one layer of dielectric. A Cu interconnection wire 240 is formed on the second barrier layer 230 in the trenched semiconductor structure 210. The second barrier layer 230 can be configured for mending some diffusion paths formed at the locations where the first barrier layer 220 has a thin thickness. In other words, as shown in FIG. 3, the Mn atoms 132 in the second barrier layer 230 can pass through the diffusion paths to the interface between the trenched semiconductor structure 210 and the first barrier layer 220 and fill up recesses 131 on the surface of the trenched semiconductor structure 210. Further, the Mn atoms 132 penetrating through the first barrier layer 220 may react with the trenched semiconductor structure 210 to produce a Mn-dielectric oxide, of which a third barrier layer is formed on the trenched semiconductor structure 210.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A self-forming barrier structure comprising:
a silicon-containing substrate;
a first barrier layer formed on the silicon-containing substrate; and
a second barrier layer formed of a copper-containing alloy on the first barrier layer;
wherein the copper-containing alloy comprises copper and at least one other metal which diffuses faster than copper and is not inter-miscible with copper.

2. The self-forming barrier structure according to claim 1, wherein the silicon-containing substrate comprises silicon, silicon oxide, or the combination thereof

3. The self-forming barrier structure according to claim 1, wherein the first barrier layer comprises ruthenium nitride (RuN).

4. The self-forming barrier structure according to claim 3, wherein the first barrier layer is formed on the silicon-containing substrate by sputtering ruthenium in a chamber filled with nitrogen gas.

5. The self-forming barrier structure according to claim 3, wherein the first barrier layer is configured for improving thermal stability of the barrier structure.

6. The self-forming barrier structure according to claim 1, wherein the second barrier layer comprises copper-manganese (CuMn) alloy.

7. The self-forming barrier structure according to claim 6, wherein the second barrier layer further functions as a copper crystal seed.

8. The self-forming barrier structure according to claim 6, wherein a part of manganese (Mn) atoms in the second barrier layer penetrate through the first barrier layer to the silicon-containing substrate, so as to fill up recesses on the silicon-containing substrate.

9. The self-forming barrier structure according to claim 8, further comprising a third barrier layer formed of manganese-silicon (MnSi) oxide due to a reaction between the silicon-containing substrate and the part of manganese (Mn) atoms penetrating through the first barrier layer.

10. The self-forming barrier structure according to claim 3, wherein the first barrier layer has a thickness in the range between 1 nm and 10 nm.

11. The self-forming barrier structure according to claim 6, wherein the second barrier layer has a thickness in the range between 50 nm and 150 nm.

12. A semiconductor device having a self-forming barrier, comprising:
a trenched semiconductor structure;
a first barrier layer formed on the trenched semiconductor structure; and
a second barrier layer formed of a copper-containing alloy on the first barrier layer;
wherein the copper-containing alloy comprises copper and at least one other metal which diffuses faster than copper and is not inter-miscible with copper.

13. The semiconductor device according to claim 12, wherein the trenched semiconductor structure comprises at least one layer of dielectric.

14. The semiconductor device according to claim 12, wherein the first barrier layer comprises ruthenium nitride (RuN).

15. The semiconductor device according to claim 14, wherein the first barrier layer is formed on the trenched semiconductor structure by sputtering ruthenium in a chamber filled with nitrogen gas.

16. The semiconductor device according to claim 14, wherein the first barrier layer is configured for improving thermal stability of the barrier structure.

17. The semiconductor device according to claim 12, wherein the second barrier layer comprises copper-manganese (CuMn) alloy.

18. The semiconductor device according to claim 17, wherein the second barrier layer further functions as a copper crystal seed.

19. The semiconductor device according to claim 17, wherein a part of manganese (Mn) atoms in the second barrier layer penetrate through the first barrier layer to the trenched semiconductor structure, so as to fill up recesses on the trenched semiconductor structure.

20. The semiconductor device according to claim 19, further comprising a third barrier layer formed of manganese-silicon (MnSi) oxide due to a reaction between the trenched semiconductor structure and the part of manganese (Mn) atoms penetrating through the first barrier layer.

21. The semiconductor device according to claim 14, wherein the first barrier layer has a thickness in the range between 1 nm and 10 nm.

22. The semiconductor device according to claim 17, wherein the second barrier layer has a thickness in the range between 50 nm and 150 nm.
